(19) United States
(12) Patent Application Publication
(10) Pub. No.: US 2026/0074159 A1
(43) Pub. Date: Mar. 12, 2026

(54) PLASMA PROCESSING APPARATUS

(71) Applicants: Beijing E-Town Semiconductor Technology Co., Ltd., Beijing (CN); Mattson Technology, Inc., Fremont, CA (US)

(72) Inventors: Jianpin Zheng, Singapore (SG); Saikumar Kodumuri, Singapore (SG); Chian Siang Tan, Singapore (SG); Subrahmanyam Venkata Rama Kommisetti, Singapore (SG); Michael van Abbema, Singapore (SG); Ludovic Goffart, Singapore (SG); Darius Da Rui Sim, Singapore (SG)

(21) Appl. No.: 19/323,635

(22) Filed: Sep. 9, 2025

Related U.S. Application Data
(60) Provisional application No. 63/692,444, filed on Sep. 9, 2024.

(51) Int. Cl. H01J 37/32

(52) U.S. Cl. CPC H01J 37/32596; H01J 37/32422; H01J 2237/332; H01J 2237/3346

(57) ABSTRACT

A plasma processing apparatus is provided. The apparatus includes a processing chamber; a workpiece support in the processing chamber configured to support a workpiece; and a hollow cathode in the processing chamber configured to produce a plasma in the processing chamber. The hollow cathode is disposed between the workpiece support and the top of the processing chamber. The apparatus includes a gas distribution system configured to provide process gas to the processing chamber. Methods for processing workpieces are also provided.

### CROSS REFERENCE TO PRIORITY APPLICATIONS

The present disclosure claims priority to U.S. Provisional Application Ser. No. 63/692,444, filed Sep. 9, 2024, the entirety of which is incorporated by reference herein.

### FIELD

The present disclosure relates generally to a plasma processing apparatus for plasma processing of a workpiece. More specifically, the present disclosure is directed to a plasma processing system including a hollow cathode.

### BACKGROUND

RF plasmas are used in the manufacture of devices such as integrated circuits, micromechanical devices, flat panel displays, and other devices. RF plasma sources used in modern plasma etch applications are required to provide a high plasma uniformity and a plurality of plasma controls, including independent plasma profile, plasma density, and ion energy controls. RF plasma sources typically must be able to sustain a stable plasma in a variety of process gases and under a variety of different conditions (e.g., gas flow, gas pressure, etc.). In addition, it is desirable that RF plasma sources produce a minimum impact on the environment by operating with reduced energy demands and reduced EM emission.

Problems with plasma processing can include processing uniformity and difficulty processing only certain portions of a workpiece while not processing or damaging other portions of the workpiece. For instance, for certain applications it may be desirable to etch or remove materials uniformly (e.g., same amount in the center part than in the perimeter) while not damaging or removing the material layer present below. Accordingly, improved plasma processing apparatuses and systems are needed.

### SUMMARY

Aspects and advantages of embodiments of the present disclosure will be set forth in part in the following description, or may be learned from the description, or may be learned through practice of the embodiments.

Aspects of the present disclosure are directed to a plasma processing apparatus. The plasma processing apparatus includes a processing chamber, a workpiece support in the processing chamber configured to support a workpiece; and a hollow cathode in the processing chamber configured to produce a plasma in the processing chamber. The hollow cathode is disposed between the workpiece support and a top of the processing chamber. The plasma processing apparatus includes a gas distribution system configured to provide process gas to the processing chamber.

Aspects of the present disclosure are directed to a processing system for processing a plurality of workpieces. The system includes a processing chamber; a workpiece support in the processing chamber configured to support a workpiece; and a hollow cathode disposed in the processing chamber configured to produce a plasma in the processing chamber. The hollow cathode is adjacent to a top of the processing chamber. The system includes a gas distribution system configured to provide process gas to the processing chamber and a controller configured to operate one or more of the workpiece support, the hollow cathode, or the gas distribution system to implement a plasma treatment process.

Aspects of the present disclosure are directed to a method for processing a workpiece in a plasma processing apparatus. The method includes placing the workpiece on a workpiece support disposed in a processing chamber of the plasma processing apparatus; performing a plasma treatment process on the workpiece in the processing chamber. Performing the plasma treatment process in the processing chamber includes generating a plasma in the processing chamber using a hollow cathode between the workpiece support and a top of the processing chamber and exposing the workpiece to the plasma.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts a cross-sectional schematic view of an example plasma processing apparatus according to example embodiments of the present disclosure;

FIG. 2 depicts a cross-sectional perspective view of a hollow cathode according to example embodiments of the present disclosure;

FIG. 3A depicts a cross-sectional schematic view of a portion of a hollow cathode according to example embodiments of the present disclosure;

FIG. 3B depicts a cross-sectional schematic view of a portion of a hollow cathode according to example embodiments of the present disclosure;

FIG. 4 depicts a top down view of a hollow cathode according to example embodiments of the present disclosure;

FIG. 5 depicts a bottom up view of a hollow cathode according to example embodiments of the present disclosure;

FIG. 6 depicts a cross-sectional schematic view of an example plasma processing apparatus having a two-piece hollow cathode according to example embodiments of the present disclosure;

FIG. 7 depicts a cross-sectional perspective view of a two-piece hollow cathode according to example embodiments of the present disclosure;

FIG. 8 depicts a bottom up view of a two-piece hollow cathode according to example embodiments of the present disclosure;

FIG. 9 depicts a cross-sectional schematic view of a portion of a two-piece hollow cathode according to example embodiments of the present disclosure;

FIG. 10 depicts a top down view of a top of a processing chamber having one or more gas supply lines therein according to example embodiments of the present disclosure;

FIG. 11 depicts a cross-sectional perspective view of a two-piece hollow cathode, processing chamber top, and RF connections according to example embodiments of the present disclosure;

FIG. 12 depicts a perspective view of a two-piece hollow cathode and RF connections according to example embodiments of the present disclosure; and

FIG. 13 depicts a flow chart diagram of a method for processing a workpiece according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Aspects of the present disclosure are discussed with reference to a “workpiece” “wafer” or semiconductor wafer for purposes of illustration and discussion. Those of ordinary skill in the art, using the disclosures provided herein, will understand that the example aspects of the present disclosure can be used in association with any semiconductor workpiece or other suitable workpiece. In addition, the use of the term “about” in conjunction with a numerical value is intended to refer to within ten percent (10%) of the stated numerical value. A “pedestal” refers to any structure that can be used to support a workpiece.

Conventional plasma processing apparatuses may include a processing chamber for treating one or more workpieces with plasma. Such chambers generally include a plasma generation source (e.g., an induction coil) on or around at least a portion of the chamber. As devices on workpieces are shrinking it has become increasingly important for low plasma damage on features and devices on the workpieces after plasma treatment processes, such as etching. To reduce plasma damage, plasmas have been generated using pulsing technology to lower ion bombardment thus reducing damage to structure on the workpiece. Generating plasma using pulsing technology, however, is not an efficient use of power and energy and increases the cost to generate plasma and costs to operate plasma processing devices. Further, processing uniformity is also critical to ensure proper function and performance for workpieces.

According to examples of the present disclosure, a plasma processing apparatus is disclosed that includes a processing chamber, a workpiece support in the processing chamber configured to support a workpiece during processing and a hollow cathode in the processing chamber. The hollow cathode is configured to produce a plasma in the processing chamber. The hollow cathode is between the workpiece support and the top of the processing chamber. A gas distribution system for supplying process gas to the processing chamber is also provided. The hollow cathode is configured to generate a low electron temperature species, which minimizes ion bombardment thus decreasing plasma damage on the workpiece.

The plasma processing apparatus according to example embodiments of the present disclosure can provide numerous benefits and technical effects. For instance, plasma processing apparatus provides an efficient way to ignite and generate plasma, such as a low electron temperature species plasma, reducing overall operational costs. Further, the plasma processing apparatus provides a hollow cathode having radial tunability to facilitate workpiece uniformity during plasma treatment processes.

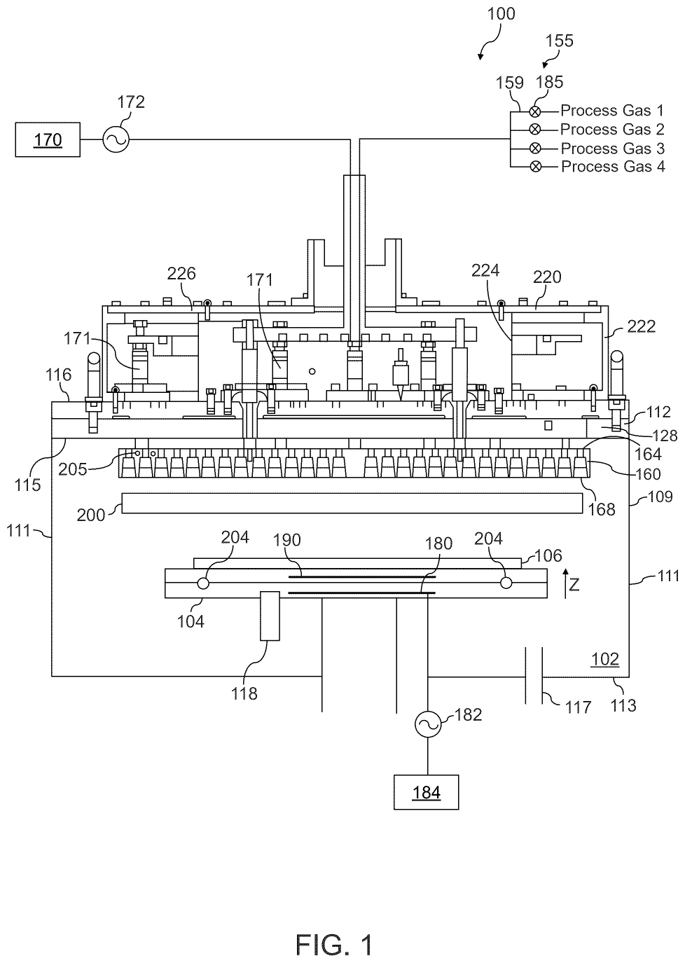

FIG. 1 depicts a plasma processing apparatus 100 according to an example embodiment of the present disclosure. The plasma processing apparatus 100 includes a processing chamber 109 defining an interior space 102. A workpiece support 104 (e.g., pedestal) is used to support a workpiece 106, such as a semiconductor wafer, within the interior space 102. Workpiece support 104 can include one or more support pins, such as at least three support pins, extending from workpiece support 104. (Not shown). In some embodiments, workpiece support 104 can be spaced from the top 112 of the processing chamber 109. The processing chamber 109 includes one or more sidewalls 111, a top 112, and a bottom 113. The top 112 and/or bottom 113 can form a flat surface or can be curved or slightly domed. The top 112 has a first surface 115 facing the interior space 102 of the processing chamber 109 and a second surface 116 opposite from the first surface 115 that faces externally. In embodiments, a top plate 128 is disposed along the top 112 of the processing chamber 109. The sidewalls 111, top 112, and/or bottom 113 of the processing chamber 109 can be formed from a metal material or a coated metal material. For instance, the sidewalls 111, top 112, and/or bottom 113 can be formed from a metal material that is coated with a dielectric material. For instance, the surfaces of the sidewalls 111, top 112, and/or bottom 113 facing the interior space 102 can be coated with a dielectric material.

An exhaust 117 can be located about the bottom 113 of the processing chamber 109 and can be connected to a pump in order to maintain a desired vacuum environment or other desired pressure condition in the processing chamber 109. In embodiments, the exhaust is located in a central location under the workpiece 106 and workpiece support 104. One or more vacuum pumps can be configured to maintain a vacuum (e.g., VAT valve) in the processing chamber 109. Further, process gas flow in and out of the processing chamber 109 can be adjusted to achieve the desired vacuum pressure in the processing chamber 109. In embodiments, the vacuum pressure is from about 0.01 Torr to about 10 Torr, such as from about 0.5 Torr to about 9 Torr, such as from about 1 Torr to about 8 Torr, such as from about 2 Torr to about 6 Torr. In some embodiments, the vacuum pressure is from about 0.05 Torr to about 1 Torr, from 0.3 Torr to about 0.8 Torr, from about 0.5 Torr to about 0.7 Torr. The exhaust 117 can also be utilized to evacuate process gas from the processing chamber 109. The vacuum pressure can be selected based on factors such as the desired process (e.g., etch or material deposition) and the workpiece materials.

As shown in FIG. 1, according to example aspects of the present disclosure, the plasma processing apparatus 100 can include a gas delivery system 155 configured to deliver process gas to the processing chamber 109, for instance, via a gas distribution channel or other distribution system (e.g., showerhead). The gas delivery system 155 can include a plurality of feed gas lines 159. The feed gas lines 159 can be controlled using valves and/or gas flow controllers 185 to deliver a desired amount of gases into the processing chamber 109 as process gas. The gas delivery system 155 can be used for the delivery of any suitable process gas. As used herein “process gas” refers to any suitable gas and includes vapors. Example process gases include oxygen-containing gases (e.g., O₂, O₃, N₂O, H₂O), hydrogen-containing gases (e.g., H₂, D₂), nitrogen-containing gases (e.g., N₂, NH₃, N₂O), fluorine-containing gases (e.g., CF₄, C₂F₄, CHF₃, CH₂F₂, CH₃F, SF₆, NF₃), hydrocarbon-containing gases (e.g., CH₄), or combinations thereof. Other feed gas lines containing other gases can be added as needed. In some embodiments, the process gas can be mixed with an inert gas that can be called a “carrier” gas, such as He, Ar, Ne, Xe, or N₂. A gas flow controller 185 (e.g., mass flow controller(s)) can be used to control a flow rate of each feed gas line to flow a process gas into the processing chamber 109.

A hollow cathode 160 is within the interior space 102 of the processing chamber 109. The hollow cathode 160 can be disposed generally in a top portion of the interior space opposite from the workpiece support 104. The hollow cathode 160 can have a first surface 164 facing the top 112 of the processing chamber 109 and a second surface 168 facing the workpiece support 104. When in a processing position, the distance between the hollow cathode 160 and the workpiece 106 may be in a range from about 20 mm to about 160 mm, such as from about 30 mm to about 150 mm, such as from about 40 mm to about 140 mm, such as from about 50 mm to about 130 mm, such as from about 60 mm to about 120 mm, such as from about 70 mm to about 110 mm, such as from about 80 mm to about 100 mm. The hollow cathode 160 can be formed from conductive materials, such as metal or metal alloys. In embodiments, the hollow cathode 160 is formed from metal. The hollow cathode 160 can be coated with a dielectric material.

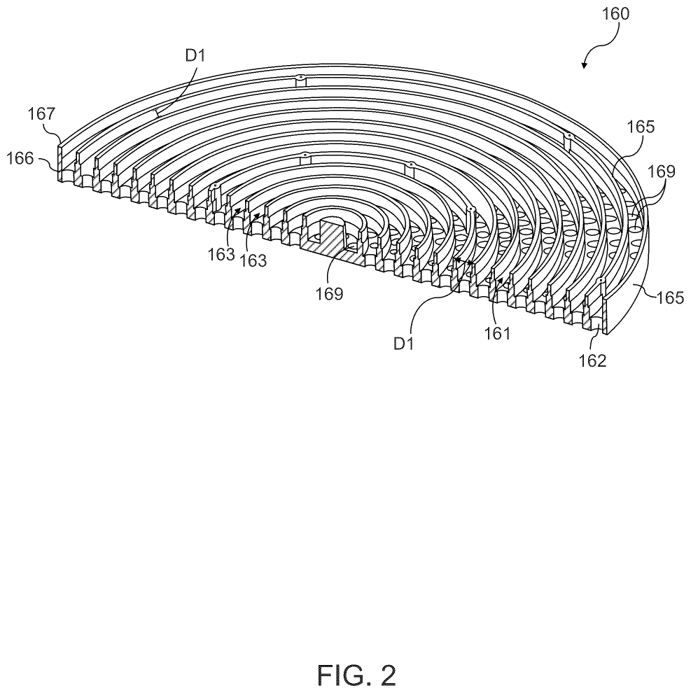

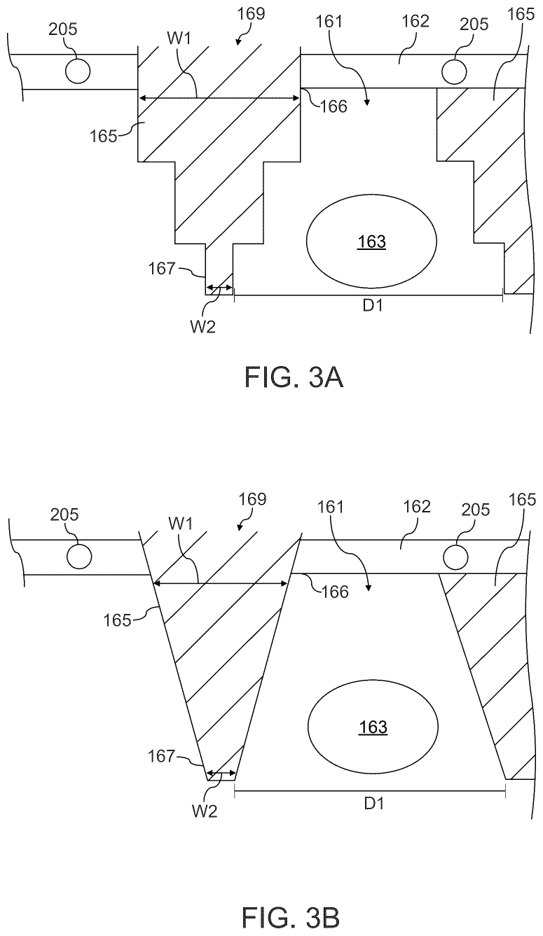

As shown in FIGS. 2, 3A, and 3B, in embodiments, the hollow cathode 160 includes a plate body 162 having a first side facing the top 112 of the processing chamber and a second side facing the workpiece support 104. A plurality of fins 165 are disposed on the second side of the plate body 162 of the hollow cathode 160. In embodiments, the plurality of fins 165 are disposed as annular, equidistance, concentric circles expanding out from a center of the plate body 162. Each of the fins 165 has a first end 166 coupled to the plate body 162 and a second end 167 (e.g., terminal end) extending from the first end 166 towards the workpiece support 104. Each of the fins 165 can be a solid material having no gaps or apertures therein. In embodiments, the fins 165 have a width (W1) along the first end 166 that is greater than a width (W2) along the second end 167 of the fins 165. In certain embodiments, as shown in FIG. 3A, the width of the fin 165 along the first end 166 can decrease in a stepwise manner along the length of the fin 165. In other embodiments, however, the width of the fin 165 can decrease in a linear fashion along the length (L) of the fin from the first end 166 to the second end 167, as shown in FIG. 3B.

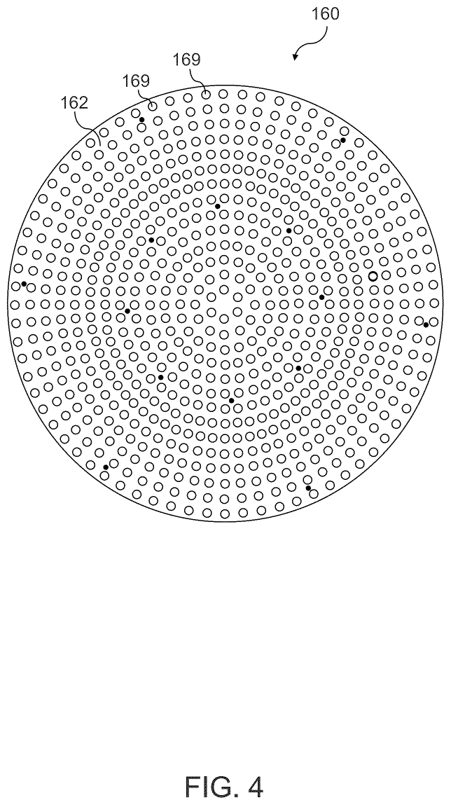

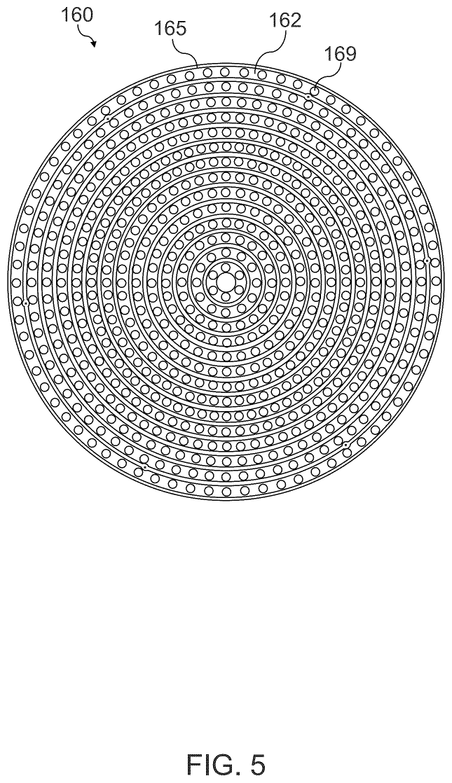

One or more (e.g., a plurality of) channels 161 can be formed between each of the adjacently spaced fins 165. For instance, the hollow cathode can include from about 2 channels to about 50 channels, such as from about 10 channels to about 20 channels. Any number of fins 165 and channels 161 can be utilized without departing from the scope of the present disclosure. One or more gas apertures 169 are disposed within the plate body 162 of the hollow cathode 160 between each of the adjacently spaced fins 165. For instance, one or more gas apertures 169 are disposed within the plate body 162 formed within the channel 161. The gas apertures 169 are configured to facilitate process gas delivery from the gas delivery system 155 to the hollow cathode 160 and, more specifically, to the one or more channels 161 of the hollow cathode 160. FIGS. 4-5 depict example gas aperture 169 patterns formed within the plate body 162 of the hollow cathode 160. For instance, FIG. 4 depicts a top down view of the hollow cathode 160 showing a plurality of the gas apertures 169, while FIG. 5 depicts a bottom up view of the hollow cathode 160 showing the plurality of gas apertures 169 disposed between the fins 165 of the hollow cathode 160. The diameter of the gas apertures 169 and the channel's width of D1 in 161 can be adjusted based on desired process parameters such as the type of pressure or plasma desired.

One or more plasma generation zones 163 are formed within one or more channels 161 of the hollow cathode 160. For instance, during operation of the hollow cathode 160, the hollow cathode 160 can be electrically coupled to a generator 170 (shown in FIG. 1), that when supplied with RF power, induces a plasma in the process gas in the plasma generation zones 163 of the hollow cathode 160. For instance, as depicted in FIG. 1, an RF generator 170 (e.g., energy source) can be configured to provide electromagnetic energy through a matching network 172 to the hollow cathode 160. For instance, when supplied with RF power, the hollow cathode 160 provides energy to excite electrons from the process gas creating free electrons that facilitate plasma creation in the plasma generation zones 163.

Given the configuration of the hollow cathode 160, electrically charged plasma species (e.g., electrons and ions) can become trapped within the plasma generation zones 163 and can resonate within the plasma generation zone 163 creating a high density plasma. By high density plasma, is meant a plasma having 1-3 orders of magnitude higher of electron density as compared to a plasma generated by a capacitively coupled plasma source. For example, the hollow cathode 160 can provide a plasma having an electron density of about 10¹⁰ cm⁻³ to about 10¹⁵ cm⁻³, such as about 10¹³ cm⁻³. Within the hollow cathode 160, positive ions and high-energy electrons trapped between the walls of the hollow cathode 160 make many collisions with the process gas, thus ionizing the process gas and generating more electrons. Radicals created by collisions with the electrons and ions can escape, making the hollow cathode 160 an efficient producer of neutral radicals. Given the configuration of the hollow cathode 160 as described, high-density plasma can be generated due to the greatly enhanced probability of electron collisions within the plasma generation zones 163 of the hollow cathode 160.

Further, as shown in FIG. 3, there is a distance D1 located between each adjacently spaced fin 165. The distance can be modified in order to tune or affect the plasma in the hollow cathode 160. For instance, D1 can be larger or increased when lower pressure plasma processing is desirable. Further, D1 can be smaller or decreased when higher pressure plasma processing is desirable. In embodiments, D1 ranges from about 2 mm to about 10 mm, such as from about 3 mm to about 9 mm, such as from about 4 mm to about 8 mm, such as from about 5 mm to about 7 mm. In certain embodiments, the distance D1 can be tuned depending on the specific process gas and/or process pressure. For instance, in embodiments where a nitrogen-containing gas is used and the pressure is about 0.7 Torr, the distance D1 can be between about 2 mm to about 10 mm, such as about 9 mm. In other embodiments, where the process gas contains a mixture of a fluorine-containing gas (e.g., CF₄), an oxygen-containing gas (e.g., O₂) and a carrier gas (e.g., Ar), and the pressure is about 0.3 Torr, the distance D1 can be between about 6 mm and to about 10 mm, such as about 9 mm.

The hollow cathode 160 can be fluid cooled. One or more conduits 205 can be disposed on the hollow cathode 160, for instance, the conduits 205 can be disposed internally in the hollow cathode 160. In other embodiments, it is contemplated that the conduits can be disposed on an external surface or surfaces of the hollow cathode 160 (not shown). Fluid can be flowed through the conduits 205 to cool the hollow cathode 160 either before, during, or after operation of the hollow cathode 160. Suitable fluids can include liquids or gases, including, but not limited to coolant fluids, water, and combinations thereof. Cooling of the hollow cathode 160 can facilitate operation of the hollow cathode 160 at higher powers to generate plasma at high density without the risk of overheating and with a reduced risk of sputtering of the cathode material.

Referring back to FIG. 1, in embodiments, the plasma processing apparatus 100 can include a filtering grid 200. The filtering grid 200 can be used to perform ion filtering, plasma uniformity tuning, and/or UV light block from a mixture generated by plasma in the processing chamber 109 to generate a filtered mixture. The filtered mixture can be exposed to the workpiece 106 in the processing chamber 109. In some embodiments, the filtering grid 200 can be a multi-plate filtering grid.

In some embodiments, the filtering grid 200 can be made of metal (e.g., aluminum) or other electrically conductive material. In some embodiments, the filtering grid 200 can be made from either an electrically conductive material or dielectric material (e.g., quartz, ceramic, etc.). In some embodiments, filtering grid 200 can be made of other materials, such as silicon or silicon carbide. In the event the filtering grid 200 is made of metal or other electrically conductive material, the filtering grid can be grounded. For instance, suitable grounding components can be placed through the top 112 or the bottom 113 of the processing chamber 109 and electrically coupled to the filtering grid 200 to ground the filtering grid 200. (Not shown). In embodiments, the filtering grid 200 is grounded to prevent charging of the filtering grid 200 during workpiece processing.

In some embodiments, the filtering grid 200 can be configured to filter ions with an efficiency greater than or equal to about 90%, such as greater than or equal to about 95%. A percentage efficiency for ion filtering refers to the amount of ions removed from the mixture relative to the total number of ions in the mixture. For instance, an efficiency of about 90% indicates that about 90% of the ions are removed during filtering. An efficiency of about 95% indicates that about 95% of the ions are removed during filtering.

In some embodiments, the filtering grid 200 can be a multi-plate filtering grid. The multi-plate filtering grid can have multiple filtering grid plates in parallel. The arrangement and alignment of holes in the grid plate can be selected to provide a desired efficiency for ion filtering, such as greater than or equal to about 95%, plasma uniformity tuning, and/or UV light block to reach the workpiece 106. For instance, the filtering grid 200 can include a first grid plate and a second grid plate that are spaced apart in parallel relationship to one another. The first grid plate and the second grid plate can be separated by a distance.

The first grid plate can have a first grid pattern having a plurality of holes. The second grid plate can have a second grid pattern having a plurality of holes. The first grid pattern can be the same as or different from the second grid pattern. Charged particles can recombine on the walls in their path through the holes of each grid plate in the filtering grid 200. Neutral species (e.g., radicals) can flow relatively freely through the holes in the first grid plate and the second grid plate. The size of the holes and thickness of each grid plate and can affect transparency for both charged and neutral particles.

Referring back to FIG. 1, the workpiece support 104 can include a bias source having a bias electrode 180 in the workpiece support 104. The bias electrode 180 can be coupled to an RF power generator 184 via a suitable matching network 182. In some embodiments, the workpiece support 104 is configured such that a DC bias can be applied to the workpiece 106. In some embodiments, DC power is applied to the bias electrode 180 located in the workpiece support 104. The DC bias can be applied to generate an electric field such that certain ions species can be attracted and/or accelerated towards the workpiece 106. With application of a DC bias to the workpiece 106, the flux of certain ionic species can be controlled. This can facilitate ion assisted radical etching or densifying film deposition on the structure of the workpiece 106. In some embodiments, the DC power applied or provided to the bias electrode is from about 50W to about 150W. Further, in embodiments the bias electrode 180 can be used to chuck (e.g., hold) the workpiece 106 on the workpiece support 104 during processing. In other embodiments, additional electrodes can be included in the workpiece support 104 to chuck the workpiece 106 on the workpiece support 104. In certain other embodiments, the workpiece support 104 can be configured to generate a pressure gradient in order to hold the workpiece 106 on the workpiece support 104 during processing.

The workpiece support 104 can also be cooled. For instance, one or more cooling conduits 204 can be disposed in or on the workpiece support 104. Fluid can be flowed through the cooling conduits 204 to cool the workpiece support 104 either before, during, or after operation of the hollow cathode 160. Suitable fluids can include liquids or gases, including, but not limited to coolant fluids, water, and combinations thereof. Cooling of the workpiece support 104 can facilitate operation of the plasma processing apparatus 100 and can reduce the risk of overheating and causing workpiece damage or non-uniformity.

The workpiece support 104 can also be heated. For instance, one or more heaters 190 can be disposed on or within the workpiece support. The heater 190 can be supplied with power to generate heat to heat both the workpiece support and the workpiece 106. For instance, heat generated by the heater 190 can heat the backside of the workpiece 106. The heater 190 can be configured to provide uniform heating across the workpiece 106 surface. For instance, the heater 190 can be configured to provide even heating distribution and can minimize temperature variations across the workpiece 106.

Both the heater 190 and the cooling conduits 204 can be utilized for temperature control during the plasma treatment process. For instance, many plasma treatment processes may require precise temperature control during workpiece processing. Thus, both the heater 190 and cooling conduits 204 can be utilized to maintain specific workpiece 106 processing temperatures during workpiece processing. Further, both the heater 190 and/or the cooling conduits 204 can be utilized to minimize workpiece 106 temperature fluctuations during processing. For instance, the heater 190 and/or cooling conduits 204 can be utilized to stabilize the temperature of the workpiece 106 during processing, including preventing thermal shocks that would negatively affect workpiece 106 performance. Further, having both the heater 190 and the cooling conduits 204 allows for different types of plasma treatment processes to be utilized within the plasma processing apparatus 100. For instance, different plasma treatment processes can require different workpiece processing temperatures. As such, use of the heater 190 and/or cooling conduits 204 can be used to adjust and control the workpiece temperature according to the specific plasma treatment process.

The workpiece support 104 can be movable in a vertical direction noted as “Z.” For instance, the workpiece support 104 can include a vertical lift 118 that can be configured to adjust a distance between the workpiece support 104 and the hollow cathode 160. As one example, the workpiece support 104 can be located in a first vertical position for processing and can be in a second vertical position for placing a workpiece 106 on or removing a workpiece 106 from the workpiece support 104. The first vertical position can be closer to the filtering grid 200 or hollow cathode 160 relative to the second vertical position.

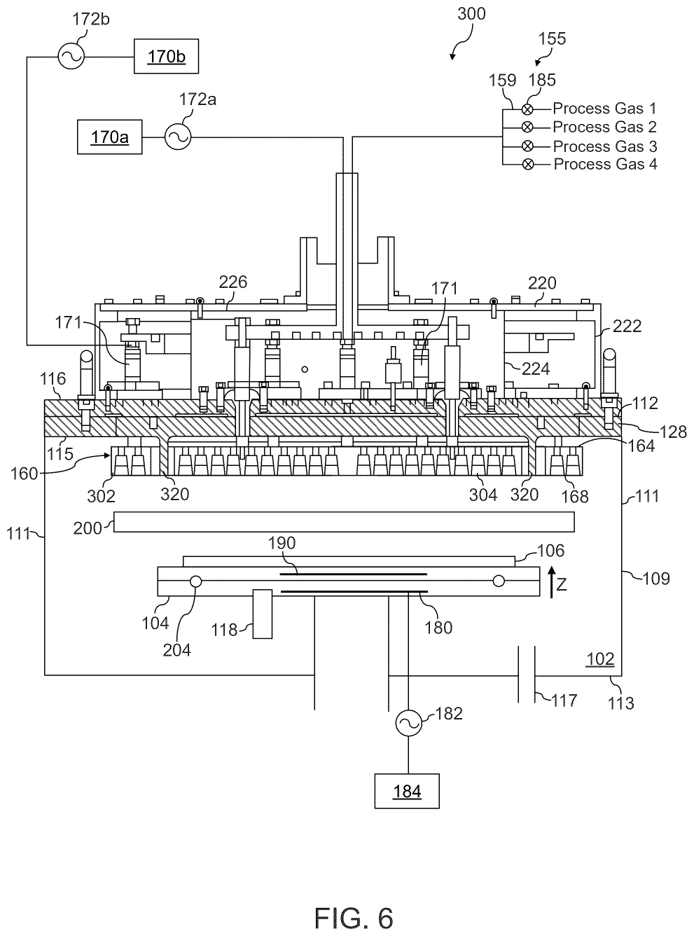

FIG. 6 depicts a plasma processing apparatus 300 similar to that of FIG. 1. More particularly, the plasma processing apparatus 300 includes a processing chamber 109 defining an interior space 102. A workpiece support 104 (e.g., pedestal) is used to support a workpiece 106, such as a semiconductor wafer, within the interior space 102. Workpiece support 104 can include one or more support pins, such as at least three support pins, extending from workpiece support 104. (Not shown). In some embodiments, workpiece support 104 can be spaced from the top 112 of the processing chamber 109. The processing chamber 109 includes one or more sidewalls 111, a top 112, and a bottom 113. The top 112 and/or bottom 113 can form a flat surface or can be curved or slightly domed. The top 112 has a first surface 115 facing the interior space 102 of the processing chamber 109 and a second surface 116 opposite from the first surface 115 that faces externally. In embodiments, a top plate 128 is disposed along the top 112 of the processing chamber 109. The sidewalls 111, top 112, and/or bottom 113 of the processing chamber 109 can be formed from a metal material or a coated metal material. For instance, the sidewalls 111, top 112, and/or bottom 113 can be formed from a metal material that is coated with a dielectric material. For instance, the surfaces of the sidewalls 111, top 112, and/or bottom 113 facing the interior space 102 can be coated with a dielectric material.

As shown in FIG. 6, the top 112 of the plasma processing apparatus 300 can include an RF cage 220 configured to isolate the RF power supplied to the hollow cathode 160 from the external environment. For instance, the RF cage 220 can include an outer wall 222, an inner wall 224, and a top 226. The RF cage 220 can be coupled to the outer surface 116 of the top 112. The inner wall 224 can surround one or more of the RF connections 171. For instance, in certain embodiments, the inner wall 224 can surround a greater number of RF connections 171 as compared to the number of RF connections 171 between the inner wall 224 and the outer wall 222. The RF cage 220 can be formed from a conductive material. In embodiments, the outer wall 222, inner wall 224 and the top 226 of the RF cage 220 are formed from a conductive material, such as a metal. The RF cage 220 can be grounded.

An exhaust 117 can be located about the bottom 113 of the processing chamber 109 and can be connected to a pump in order to maintain a desired vacuum environment or other desired pressure condition in the processing chamber 109. In some embodiments, the exhaust is located in a central location under the workpiece 106 and workpiece support 104. One or more vacuum pumps can be configured to maintain a vacuum and pressure control with valve (e.g., VAT throttle valve) in the processing chamber 109. Further, process gas flow in and out of the processing chamber 109 can be adjusted to achieve the desired vacuum pressure in the processing chamber 109. In embodiments, the vacuum pressure is from about 0.01 Torr to about 10 Torr, such as from about 0.5 Torr to about 9 Torr, such as from about 1 Torr to about 8 Torr, such as from about 2 Torr to about 6 Torr. In some embodiments, the vacuum pressure is from about 0.05 Torr to about 1 Torr, from 0.3 Torr to about 0.8 Torr, from about 0.5 Torr to about 0.7 Torr. The exhaust 117 can also be utilized to evacuate process gas from the processing chamber 109. The vacuum pressure can be selected based on factors such as the desired process (e.g., etch or material deposition) and the workpiece materials.

A hollow cathode 160 is disposed within the interior space 102 of the processing chamber 109. The hollow cathode 160 can be coupled to the top 112 of the processing chamber 109. The hollow cathode 160 can have a first surface 164 facing the top 112 of the processing chamber 109 and a second surface 168 facing the workpiece support 104. When in a processing position, the distance between the hollow cathode 160 and the workpiece 106 may be in a range from about 20 mm to about 160 mm, such as from about 30 mm to about 150 mm, such as from about 40 mm to about 140 mm, such as from about 50 mm to about 130 mm, such as from about 60 mm to about 120 mm, such as from about 70 mm to about 110 mm, such as from about 80 mm to about 100 mm. The hollow cathode 160 can be formed from metal materials, such as aluminum.

As shown, however, the hollow cathode 160 includes an outer hollow cathode 302 and an inner hollow cathode 304. The inner hollow cathode 304 and the outer hollow cathode 302 are not electrically coupled. For instance, a shield 320 is disposed between the outer hollow cathode 302 and the inner hollow cathode 304. The shield 320 can be formed as part of the top 112 of the plasma processing apparatus 300. The shield 320 can be formed from a conductive and/or dielectric material. In embodiments, the shield 320 is formed from a conductive material (e.g., metal) coated with a dielectric material.

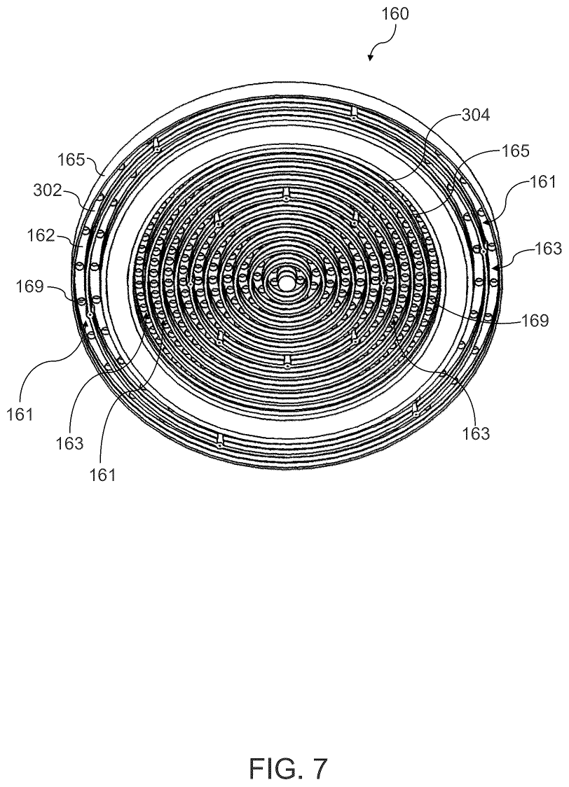

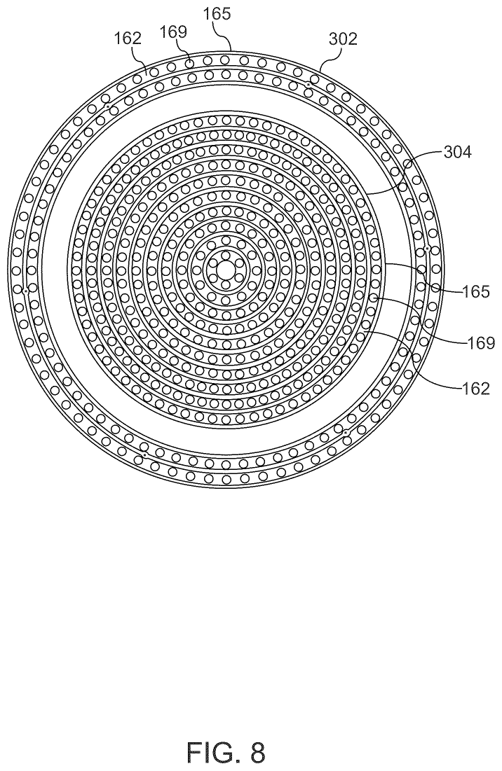

Similar to FIG. 1 and as shown in FIGS. 7-8, both the outer hollow cathode 302 and the inner hollow cathode 304 have a plurality of channels 161 that are formed between each of the adjacently spaced fins 165. Further, any number of channels 161 and fins 165 can be used without departing from the scope of the present disclosure. One or more gas apertures 169 are disposed within the plate body 162 of the hollow cathode 160 between each of the adjacently spaced fins 165. For instance, one or more gas apertures 169 are disposed within the plate body 162 formed within the channel 161. The gas apertures 169 are configured to facilitate process gas delivery from the gas delivery system 155 to the hollow cathode 160 and, more specifically, to the one or more channels 161 of the hollow cathode 160. FIGS. 7-8 depict example gas aperture 169 patterns formed within the plate body 162 of the hollow cathode 160. For instance, FIG. 7 depicts a perspective view of the hollow cathode 160 showing a plurality of the gas apertures 169, while FIG. 8 depicts a bottom-up view of the hollow cathode 160 showing the plurality of gas apertures 169 disposed between the fins 165 of the hollow cathode 160. The diameter of the gas apertures 169 and channel width D1 can be adjusted based on desired process parameters such as the type of pressure or plasma desired.

Similar to FIGS. 2-3, one or more plasma generation zones 163 are formed within the one or more channels 161 of the hollow cathode 160. For instance, during operation of the hollow cathode 160, the hollow cathode 160 can be electrically coupled to a generator 170, that when supplied with RF power, induces a plasma in the process gas in the plasma generation zones 163 of the plasma processing apparatus 300. For instance, as depicted in FIG. 6, an RF generator 170 can be configured to provide electromagnetic energy through a matching network 172 to the hollow cathode 160. For instance, when supplied with RF power, the hollow cathode 160 provides energy to excite electrons from the process gas creating free electrons that facilitate plasma creation in the plasma generation zones 163.

In embodiments, the inner hollow cathode 304 is connected to a first RF generator 170a via a first matching network 172a and the outer hollow cathode 302 is coupled to a second RF generator 170b via a second matching network 172b, where both the second matching network 172b and second RF generator 170b are different from those of the first RF generator 170a and first matching network 172a. In such a configuration, electromagnetic energy supplied to the inner hollow cathode 304 can be independently controlled with respect to the outer hollow cathode 302 and vice versa. Accordingly, during processing the energy supplied to the inner hollow cathode 304 can be increased or decreased independently from the outer hollow cathode 302. Such a configuration allows for plasma tuning to adjust for any observed workpiece non-uniformity. As such, uniformity corrections can be implemented by adjusting the energy supplied to either the inner hollow cathode 304 or the outer hollow cathode 302. In some embodiments, the plasma processing apparatus 300 includes a phase lock between the first RF generator 170a and the second RF generator 170b. The phase lock may be operable to control the RF generators 170a, 170b so that RF energy provided by the RF generators 170a, 170b remain in phase or at a specified phase difference relative to one another. Any suitable phase lock circuitry may be used to implement the phase lock.

Given the configuration of the hollow cathode 160, electrically charged plasma species (e.g., electrons and ions) can become trapped within the plasma generation zones 163 and can resonate within the plasma generation zone 163 creating a high density plasma. By high density plasma, is meant a plasma having 1-3 orders of magnitude higher of electron density as compared to a plasma generated by a capacitively coupled plasma source. For example, the hollow cathode 160 can provide a plasma having an electron density of about 10¹⁰ cm⁻³ to about 10¹⁵ cm⁻³, such as about 10¹³ cm⁻³. Within the hollow cathode 160, positive ions and high-energy electrons trapped between the walls of the hollow cathode 160 make many collisions with the process gas, thus ionizing the process gas and generating more electrons. Radicals created by collisions with the electrons and ions can escape, making the hollow cathode 160 an efficient producer of neutral radicals. Given the configuration of the hollow cathode 160 as described, high-density plasma can be generated due to the greatly enhanced probability of electron bombardment within the plasma generation zones 163 of the hollow cathode 160.

The plasma processing apparatus 300 can include a gas delivery system 155 configured to deliver process gas to the processing chamber 109, for instance, via a gas distribution channel or other distribution system (e.g., showerhead). The gas delivery system 155 can include a plurality of feed gas lines 159. The feed gas lines 159 can be controlled using gas flow controllers 185 to deliver a desired amount of gases into the processing chamber 109 as process gas. The gas delivery system 155 can be used for the delivery of any suitable process gas. As used herein “process gas” refers to any suitable gas and includes vapors. Example process gases include oxygen-containing gases (e.g., O₂, O₃, N₂O, H₂O), hydrogen-containing gases (e.g., H₂, D₂), nitrogen-containing gases (e.g., N₂, NH₃, N₂O), fluorine-containing gases (e.g., CF₄, C₂F₄, CHF₃, CH₂F₂, CH₃F, SF₆, NF₃), hydrocarbon-containing gases (e.g., CH₄), or combinations thereof. Other feed gas lines containing other gases can be added as needed. In some embodiments, the process gas can be mixed with an inert gas that can be called a “carrier” gas, such as He, Ar, Ne, Xe, or N₂. A gas flow controller 185 (e.g., mass flow controller(s)) can be used to control a flow rate of each feed gas line to flow a process gas into the processing chamber 109.

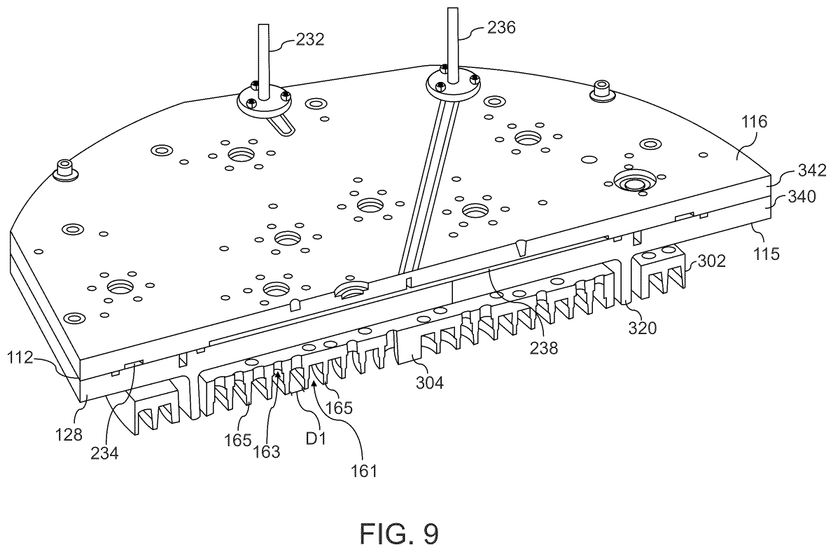

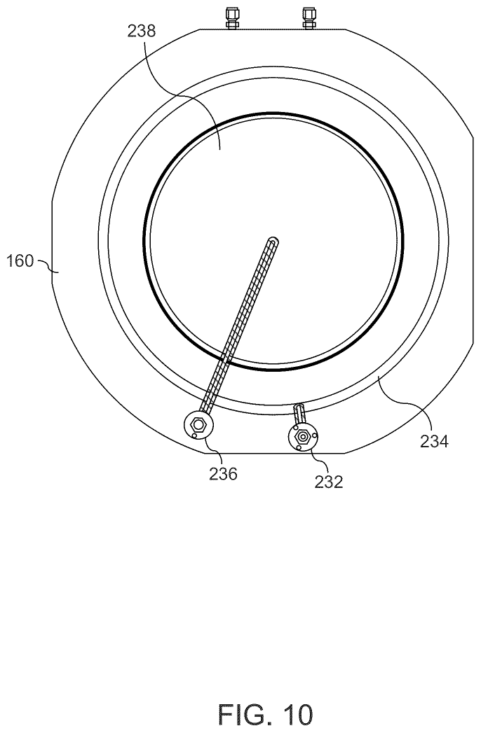

Referring to FIGS. 9-11, the gas delivery system 155 is configured to supply process gas to one or more plenums within the hollow cathode 160. For instance, a first gas supply line 232 is configured to supply process gas to a first plenum 234 that is coupled to the outer hollow cathode 302. A second gas supply line 236 is configured to supply process gas to a second plenum 238 that is coupled to the inner hollow cathode 304. In such embodiments, the amount (e.g., pressure) or type of gas supplied to the outer hollow cathode 302 can be different from that supplied to the inner hollow cathode 304. As such, workpiece uniformity can be further controlled or modified based on the type or amount of process gas supplied to the outer hollow cathode 302 versus the inner hollow cathode 304. The area of the first plenum 234 and the second plenum 238 are shown in the top down view of FIG. 10.

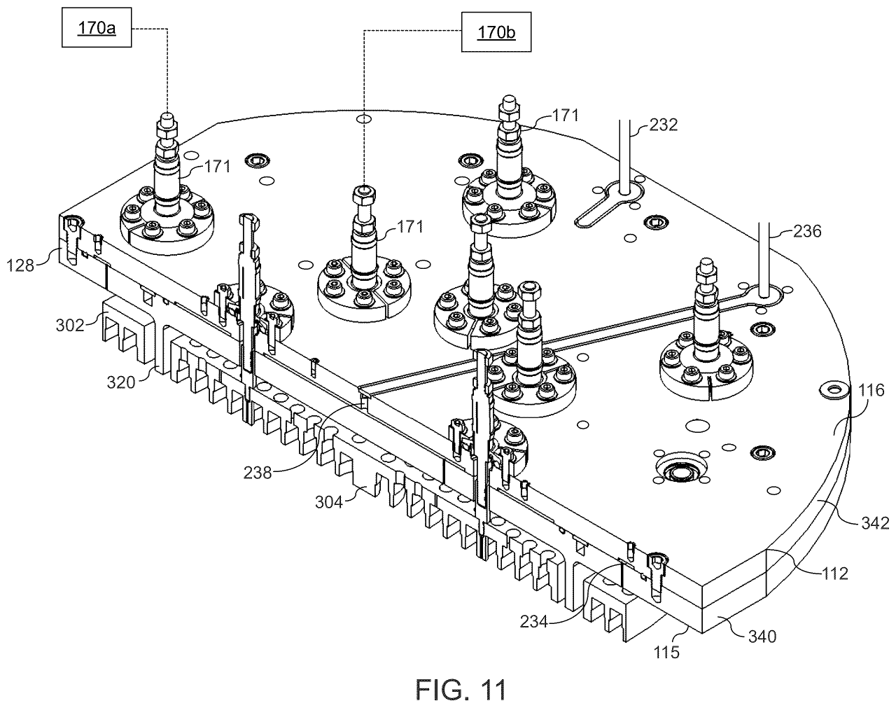

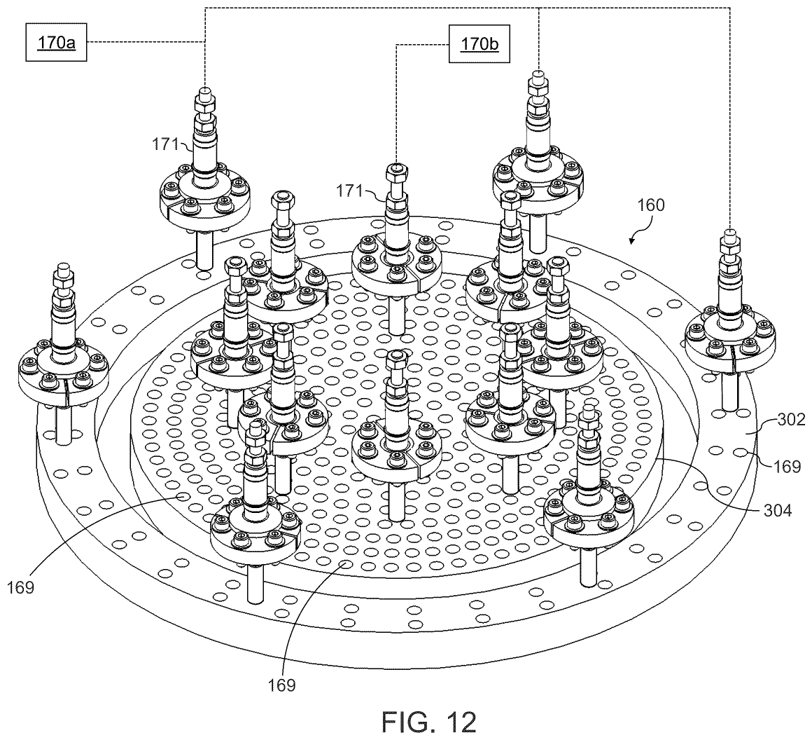

The inner hollow cathode 304 and the outer hollow cathode 302 have a shield 320 disposed therebetween as shown in FIG. 6. The top 112 includes a first portion including a base plate 340 having the shield 320 formed therein and a top plate 342. The first plenum 234 and second plenum 238 can be located in a space between the base plate 340 and the top plate 342. As shown in FIGS. 11-12, a plurality of RF connections 171 are used to couple the inner hollow cathode 304 to the first RF generator 170a and a plurality of RF connections 171 are used to couple the outer hollow cathode 302 to the second RF generator 170b. The RF connections 171 are configured to extend through the top 112, including both the base plate 340 and the top plate 342 of the top 112.

Referring back to FIG. 6, the plasma processing apparatus 300 can include a filtering grid 200. The filtering grid 200 can be used to perform ion filtering from a mixture generated by plasma in the processing chamber 109 to generate a filtered mixture. The filtered mixture can be exposed to the workpiece 106 in the processing chamber 109. In some embodiments, the filtering grid 200 can be a multi-plate filtering grid.

In some embodiments, the filtering grid 200 can be made of metal (e.g., aluminum) or other electrically conductive material. In some embodiments, the filtering grid 200 can be made from either an electrically conductive material or dielectric material (e.g., quartz, ceramic, etc.). In some embodiments, filtering grid 200 can be made of other materials, such as silicon or silicon carbide. In the event the filtering grid 200 is made of metal or other electrically conductive material, the filtering grid can be grounded. For instance, suitable grounding components can be placed through the top 112 or the bottom 113 of the processing chamber 109 and electrically coupled to the filtering grid 200 to ground the filtering grid 200. In embodiments, the filtering grid 200 is grounded to prevent charging of the filtering grid 200 during workpiece processing.

In some embodiments, the filtering grid 200 can be configured to filter ions with an efficiency greater than or equal to about 90%, such as greater than or equal to about 95%, plasma uniformity tuning, and/or block UV light from workpiece 106. A percentage efficiency for ion filtering refers to the amount of ions removed from the mixture relative to the total number of ions in the mixture. For instance, an efficiency of about 90% indicates that about 90% of the ions are removed during filtering. An efficiency of about 95% indicates that about 95% of the ions are removed during filtering.

In some embodiments, the filtering grid 200 can be a multi-plate filtering grid. The multi-plate filtering grid can have multiple filtering grid plates in parallel. The arrangement and alignment of holes in the grid plate can be selected to provide a desired efficiency for ion filtering, such as greater than or equal to about 95%, plasma uniformity tuning, and/or block UV light from workpiece 106. For instance, the filtering grid 200 can include a first grid plate and a second grid plate that are spaced apart in parallel relationship to one another.

The first grid plate and the second grid plate can be separated by a distance.

The first grid plate can have a first grid pattern having a plurality of holes. The second grid plate can have a second grid pattern having a plurality of holes. The first grid pattern can be the same as or different from the second grid pattern. Charged particles can recombine on the walls in their path through the holes of each grid plate in the filtering grid 200. Neutral species (e.g., radicals) can flow relatively freely through the holes in the first grid plate and the second grid plate. The size of the holes and thickness of each grid plate and can affect transparency for both charged and neutral particles.

Referring back to FIG. 6, the workpiece support 104 can include a bias source having a bias electrode 180 in the workpiece support 104. The bias electrode 180 can be coupled to an RF power generator 184 via a suitable matching network 182. In some embodiments, the workpiece support 104 is configured such that a DC bias can be applied to the workpiece 106. In some embodiments, DC power is applied to the bias electrode 180 located in the workpiece support 104. The DC bias can be applied to generate an electric field such that certain ions species can be attracted and/or accelerated towards the workpiece 106. With application of a DC bias to the workpiece 106, the flux of certain ionic species can be controlled. This can facilitate ion assisted radical etching or densifying film deposition on the structure of the workpiece 106. In some embodiments, the DC power applied or provided to the bias electrode is from about 50W to about 150W. Further, in embodiments the bias electrode 180 can be used to chuck (e.g., hold) the workpiece 106 on the workpiece support 104 during processing. In other embodiments, additional electrodes can be included in the workpiece support 104 to chuck the workpiece 106 on the workpiece support 104. In certain other embodiments, the workpiece support 104 can be configured to generate a pressure gradient in order to hold the workpiece 106 on the workpiece support 104 during processing.

The workpiece support 104 can also be cooled. For instance, one or more cooling conduits 204 can be disposed in or on the workpiece support 104. Fluid can be flowed through the cooling conduits 204 to cool the workpiece support 104 either before, during, or after operation of the hollow cathode 160. Suitable fluids can include liquids or gases, including, but not limited to coolant fluids, water, and combinations thereof. Cooling of the workpiece support 104 can facilitate operation of the plasma processing apparatus 300 and can reduce the risk of overheating and causing workpiece damage or non-uniformity.

The workpiece support 104 can also be heated. For instance, one or more heaters 190 can be disposed on or within the workpiece support. The heater 190 can be supplied with power to generate heat to heat both the workpiece support and the workpiece 106. For instance, heat generated by the heater 190 can heat the backside of the workpiece 106. The heater 190 can be configured to provide uniform heating across the workpiece 106 surface. For instance, the heater 190 can be configured to provide even heating distribution and can minimize temperature variations across the workpiece 106.

Both the heater 190 and the cooling conduits 204 can be utilized for temperature control during the plasma treatment process. For instance, many plasma treatment processes may require precise temperature control during workpiece processing. Thus, both the heater 190 and cooling conduits 204 can be utilized to maintain specific workpiece 106 processing temperatures during workpiece processing. Further, both the heater 190 and/or the cooling conduits 204 can be utilized to minimize workpiece 106 temperature fluctuations during processing. For instance, the heater 190 and/or cooling conduits 204 can be utilized to stabilize the temperature of the workpiece 106 during processing, including preventing thermal shocks that would negatively affect workpiece 106 performance. Further, having both the heater 190 and the cooling conduits 204 allows for different types of plasma treatment processes to be utilized within the plasma processing apparatus 300. For instance, different plasma treatment processes can require different workpiece processing temperatures. As such, use of the heater 190 and/or cooling conduits 204 can be used to adjust and control the workpiece temperature according to the specific plasma treatment process.

The workpiece support 104 can be movable in a vertical direction noted as “V.” For instance, the workpiece support 104 can include a vertical lift 118 that can be configured to adjust a distance between the workpiece support 104 and the hollow cathode 160. As one example, the workpiece support 104 can be located in a first vertical position for processing and can be in a second vertical position for placing a workpiece 106 on or removing a workpiece 106 from the workpiece support 104. The first vertical position can be closer to the filtering grid 200 relative to the second vertical position. When in a processing position, the distance between the hollow cathode 160 and the workpiece 106 may be in a range from about 20 mm to about 160 mm, such as from about 30 mm to about 150 mm, such as from about 40 mm to about 140 mm, such as from about 50 mm to about 130 mm, such as from about 60 mm to about 120 mm, such as from about 70 mm to about 110 mm, such as from about 80 mm to about 100 mm. The hollow cathode 160 can be formed from conductive materials, such as metal or metal alloys. In embodiments, the hollow cathode 160 is formed from metal. The hollow cathode 160 can be coated with a dielectric material.

As shown in FIGS. 1 and 6, the top 112 of the plasma processing apparatus 300 can include an RF cage 220 configured to isolate the RF power supplied to the hollow cathode 160 from the external environment. For instance, the RF cage 220 can include an outer wall 222, an inner wall 224, and a top 226. The RF cage 220 can be coupled to the outer surface 116 of the top 112. The inner wall 224 can surround one or more of the RF connections 171. For instance, in certain embodiments, the inner wall 224 can surround a greater number of RF connections 171 as compared to the number of RF connections 171 between the inner wall 224 and the outer wall 222. The RF cage 220 can be formed from a conductive material. In embodiments, the outer wall 222, inner wall 224 and the top 226 of the RF cage 220 are formed from a conductive material, such as a metal. The RF cage 220 can be grounded.

In some embodiments, plasma processing apparatus 100 or 300 may include a controller. (Not Shown). The controller may be configured to control the gas distribution system, the hollow cathode, the workpiece support, cooling systems, and the DC bias to implement a plasma treatment process. The controller can include one or more processors and one or more memory devices. The memory devices can store computer-readable instructions that when executed by the one or more processors cause the controller to control aspects of the plasma processing apparatus 100 or 300 to implement any of the methods disclosed herein. In some embodiments, the controller is configured to control the gas distribution system, the hollow cathode, the workpiece support, cooling systems, and the DC bias to implement a plasma treatment process (e.g., an etch process). The plasma treatment process may include certain operations. The operations may include admitting a process gas in the process chamber to the hollow cathode; providing RF power to the hollow cathode to generate a plasma from the process gas to generate a first mixture, the first mixture comprising one or more first species; optionally, filtering the one or more first species to create a filtered mixture. In certain embodiments, the operations further include providing DC power to the bias electrode. The operations can further include modifying or adjusting the power of the RF power supplied to the hollow cathode. The operations can further include modifying the amount or type of process gas supplied to the hollow cathode in the processing chamber.

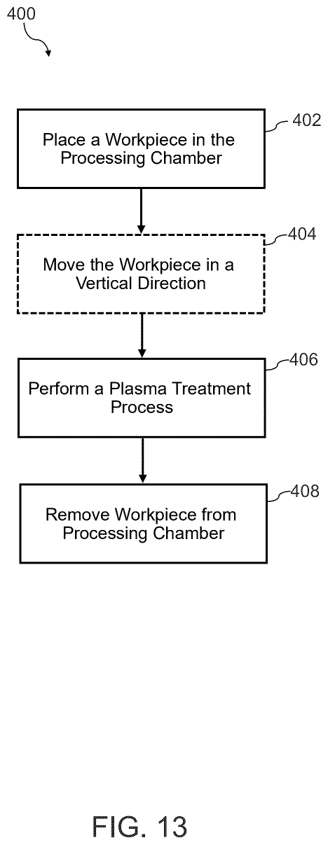

FIG. 13 depicts a flow diagram of one example method (400) according to example aspects of the present disclosure. The method (400) will be discussed with reference to the plasma processing apparatus 100 of FIGS. 1-5 by way of example. The method (400) can be implemented in any suitable plasma processing apparatus. FIG. 13 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various steps (not illustrated) can be performed without deviating from the scope of the present disclosure.

At (402), the method includes placing a workpiece 106 in the processing chamber 109 of a plasma processing apparatus 100. For instance, the workpiece 106 can be placed on a workpiece support 104 disposed in the processing chamber 109.

Optionally, at (404) the method can include moving the workpiece support 104 in a vertical direction to a processing position within the processing chamber 109. For instance, the workpiece support 104 having the workpiece 106 thereon can be moved to a position that is closer to the hollow cathode 160 for plasma processing.

At (406), the method includes performing a plasma treatment process on the workpiece 106 in the processing chamber 109. The plasma etch treatment process can selectively remove one or more material layers from the workpiece 106. In other embodiments, the treatment process includes a plasma deposition process. For instance, the plasma deposition process can selectively deposit one or more material layer on the workpiece 106. Other plasma processes can be used to modify the material layers present on the workpiece. For example, plasma-based surface treatment processes can be utilized to modify the surface morphology of the workpiece 106 or to modify the chemical composition of layers on the workpiece 106. Any other, known suitable plasma-based processing for workpieces can be performed on the workpiece 106.

The plasma treatment process can include generating a plasma in the processing chamber 109 utilizing a hollow cathode 160 disposed in the processing chamber between the workpiece support and the top of the processing chamber. The hollow cathode can be formed from metal materials, such as aluminum.

The hollow cathode 160 includes a plurality of fins 165 disposed on plate body 162 of hollow cathode 160. In embodiments, the plurality of fins 165 are disposed as annular, equidistance, concentric circles expanding out from a center of the plate body 162. Each of the fins 165 has a first end 166 coupled to the plate body 162 and a second end 167 (e.g., terminal end) extending from the first end 166 towards the workpiece support 104. Each of the fins 165 can be a solid material having no gaps or apertures therein. In embodiments, the fins 165 have a width (W1) along the first end 166 that is greater than a width (W2) along the second end 167 of the fin 165.

A plurality of channels 161 can be formed between each adjacently spaced fin 165. One or more gas apertures 169 are disposed within the plate body 162 of the hollow cathode 160 between each of the adjacently spaced fins 165. For instance, one or more gas apertures 169 are disposed within the plate body 162 formed within the channel 161. The gas apertures 169 are configured to facilitate process gas delivery from the gas delivery system 155 to the hollow cathode 160 and, more specifically, to the one or more channels 161 of the hollow cathode 160. The diameter of the gas apertures 169 and width of the channel D1 can be adjusted based on desired process parameters such as the type of pressure or plasma desired.

Plasma generation zones 163 are formed within the one or more channels 161 of the hollow cathode. For instance, during operation of the hollow cathode 160, the hollow cathode 160 can be electrically coupled to a generator 170, that when supplied with RF power, induces a plasma in the process gas in the plasma generation zones 163 of the plasma processing apparatus 100. For instance, as depicted in FIG. 1, an RF generator 170 can be configured to provide electromagnetic energy through a matching network 172 to the hollow cathode 160. For instance, when supplied with RF power, the hollow cathode provides energy to excite electrons from the process gas creating free electrons that facilitate plasma creation in the plasma generation zones 163.

Given the configuration of the hollow cathode 160, electrically charged plasma species (e.g., electrons and ions) can become trapped within the plasma generation zones 163 and can resonate within the plasma generation zone 163 creating a high density plasma. By high density plasma, is meant a plasma having 1-3 orders of magnitude higher of electron density as compared to a plasma generated by a capacitively coupled plasma source. For example, the hollow cathode 160 can provide a plasma having an electron density of about 10¹⁰ cm⁻³ to about 10¹⁵ cm⁻³, such as about 10¹³ cm⁻³. Within the hollow cathode 160, positive ions and high-energy electrons trapped between the walls of the hollow cathode 160 make many collisions with the process gas, thus ionizing the process gas and generating more electrons. Radicals created by collisions with the electrons and ions can escape, making the hollow cathode 160 an efficient producer of neutral radicals. Given the configuration of the hollow cathode 160 as described, high-density plasma can be generated due to the greatly enhanced probability of electron bombardment within the plasma generation zones 163 of the hollow cathode 160.

Further, as shown in FIG. 3, there is a distance D1 located between each adjacently spaced fin 165. The distance can be modified in order to tune or affect the plasma in the hollow cathode 160. For instance, D1 can be larger or increased when lower pressure plasma processing is desirable. Further, D1 can be smaller or decreased when higher pressure plasma processing is desirable. In embodiments, D1 ranges from about 2 mm to about 10 mm, such as from about 3 mm to about 9 mm, such as from about 4 mm to about 8 mm, such as from about 5 mm to about 7 mm. In certain embodiments, the distance D1 can be tuned depending on the specific process gas and/or process pressure. For instance, in embodiments where a nitrogen-containing gas is used and the pressure is about 0.7 Torr, the distance D1 can be between about 2 mm to about 10 mm, such as about 9 mm. In other embodiments, where the process gas contains a mixture of a fluorine-containing gas (e.g., CF₄), an oxygen-containing gas (e.g., O₂) and a carrier gas (e.g., Ar), and the pressure is about 0.3 Torr, the distance D1 can be between about 6 mm and to about 10 mm, such as about 9 mm.

When utilizing the apparatus shown in FIGS. 6-12, plasma generation zones 163 are formed within the one or more channels 161 of the inner and outer hollow cathodes 302, 304. For instance, during operation of the inner and outer hollow cathodes 302, 304, both hollow cathodes can be electrically coupled to a generator 170 (or separate generators) that when supplied with RF power, induces a plasma in the process gas in the plasma generation zones 163 of the inner and outer hollow cathodes 302, 304. For instance, as depicted in FIG. 6, a first RF generator 170a can be configured to provide electromagnetic energy through a first matching network 172a to the inner hollow cathode 304 and a second RF generator 170b can be configured to provide electromagnetic energy through a second matching network 172b to the outer hollow cathode 302. When supplied with RF power, each hollow cathode 302, 304 provides energy to excite electrons from the process gas creating free electrons that facilitate plasma creation in the plasma generation zones 163. Further, since inner hollow cathode 304 can be coupled to an RF generator that is different from that of the outer hollow cathode 302, during processing, energy supplied to the inner hollow cathode 304 can be adjusted independently from the outer hollow cathode 302 and vice versa.

Further, process gas supplied to the inner hollow cathode 304 versus the outer hollow cathode 302 can be independently controlled. For instance, process gas can be supplied to the outer hollow cathode 302 via a first gas supply line 232 configured to supply process gas to a first plenum 234 that is coupled to the outer hollow cathode 302. A second gas supply line 236 is configured to supply process gas to a second plenum 238 that is coupled to the inner hollow cathode 304. In such embodiments, the amount (e.g., pressure) or type of gas supplied to the outer hollow cathode 302 can be different from that supplied to the inner hollow cathode 304. As such, process uniformity can be further controlled or modified based on the type or amount of process gas supplied to the outer hollow cathode 302 versus the inner hollow cathode 304.

Optionally, the method can include filtering one or more species in the plasma with a filtering grid 200 disposed between the hollow cathode 160 and the workpiece 106 in the processing chamber 109. For instance, species generated in the plasma can pass through a filtering grid 200 to filter ions in the species. Neutral radicals passing through the filtering grid 200 are thus filtered to create a filtered mixture.

In some embodiments, the filtering grid 200 can be configured to filter ions with an efficiency greater than or equal to about 90%, such as greater than or equal to about 95%. A percentage efficiency for ion filtering refers to the amount of ions removed from the mixture relative to the total number of ions in the mixture. For instance, an efficiency of about 90% indicates that about 90% of the ions are removed during filtering. An efficiency of about 95% indicates that about 95% of the ions are removed during filtering.

The method includes exposing the workpiece 106 to the plasma, such as exposing the workpiece 106 to radicals in the plasma or, where filtering is performed, exposing the workpiece 106 to the filtered mixture. For instance, exposure of the workpiece 106 to the plasma species can result in the removal of material from at least a portion of certain material layers present on the workpiece 106. When radicals are exposed to the workpiece, the radicals may etch material layers from the workpiece 106. In other embodiments, exposure of the workpiece 106 to the plasma species (e.g., radicals) can deposit a layer of material on the workpiece 106.

During exposure of the workpiece 106 the plasma species the workpiece 106 is supplied with DC power via a DC bias to the bias electrode 180 in the workpiece support 104. Application of the DC bias to the workpiece 106 may accelerate certain species from the plasma to the surface of the workpiece 106. For example, in some embodiments, application of the DC bias to the workpiece 106 may result in accelerating certain etchant species, such as fluorine radical etchants, to the surface of the workpiece resulting in the removal of the material layer that is perpendicular to the flow of the one or more species of the plasma. In some embodiments, application of the DC bias to the workpiece may result in accelerating certain deposition or layer forming species towards the surface of the workpiece resulting in the formation of additional layers or films on the workpiece 106.

The hollow cathode 160 can be fluid cooled. For instance, one or more conduits 205 can be disposed on the hollow cathode 160. The conduits 205 can be disposed internally in the hollow cathode 160. In other embodiments, it is contemplated that the conduits can be disposed on an external surface or surfaces of the hollow cathode 160. Fluid can be flowed through the conduits 205 to cool the hollow cathode 160 either before, during, or after operation of the hollow cathode 160. Suitable fluids can include liquids or gases, including, but not limited to coolant fluids, water, and combinations thereof. Cooling of the hollow cathode 160 can facilitate operation of the hollow cathode 160 at higher powers to generate plasma at high density without the risk of overheating and with a reduced risk of sputtering of the cathode material.

At (408), the method can include removing the workpiece 106 from the processing chamber 109. Additional process steps can be performed prior to removing the workpiece from the processing chamber without deviating from the scope of the present disclosure. The workpiece 106 can be removed from workpiece support 104 in the processing chamber 109. To facilitate removal of the workpiece 106, the workpiece support 104 can be lowered to a non-processing position in the processing chamber 109. The workpiece 106 can be lifted from the surface of the workpiece support 104 and removed from the processing chamber 109 by a robot arm. The plasma processing apparatus can then be conditioned for future processing of additional workpieces.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A plasma processing apparatus, comprising:
a processing chamber;
a workpiece support in the processing chamber configured to support a workpiece;
a hollow cathode in the processing chamber configured to produce a plasma in the processing chamber, wherein the hollow cathode is disposed between the workpiece support and a top of the processing chamber; and
a gas distribution system configured to provide process gas to the processing chamber.

2. The plasma processing apparatus of claim 1, wherein the hollow cathode has a first side facing the top of the processing chamber and a second side facing the workpiece support.

3. The plasma processing apparatus of claim 2, comprising a plurality of fins extending from the second side of the hollow cathode.

4. The plasma processing apparatus of claim 3, wherein each of the fins comprises a first end coupled to the second side and a second end extending therefrom, wherein a first width of the first end is greater than a second width at the second end.

5. The plasma processing apparatus of claim 4, wherein a total width of the fin decreases in a stepwise manner from the first end to the second end.

6. The plasma processing apparatus of claim 4, wherein a total width of the fin decreases in a linear manner from the first end to the second end.

7. The plasma processing apparatus of claim 1, wherein the hollow cathode comprises a plurality of gas apertures configured to provide the process gas to the processing chamber.

8. The plasma processing apparatus of claim 7, wherein the one or more of the plurality of gas apertures are between adjacent fins of the hollow cathode.

9. The plasma processing apparatus of claim 1, wherein a plasma generation zone is located between each adjacent fin of the hollow cathode.

10. The plasma processing apparatus of claim 1, wherein the hollow cathode is operably coupled to one or more energy sources.

11. The plasma processing apparatus of claim 1, wherein the hollow cathode comprises an outer hollow cathode and an inner hollow cathode.

12. The plasma processing apparatus of claim 11, wherein the outer hollow cathode and inner hollow cathode are not electrically coupled.

13. The plasma processing apparatus of claim 11, comprising a shield separating the outer hollow cathode from the inner hollow cathode.

14. The plasma processing apparatus of claim 11, wherein the outer hollow cathode is electrically coupled to a first energy source and the inner hollow cathode is coupled to a second energy source that is different from the first energy source.

15. The plasma processing apparatus of claim 11, wherein the gas distribution system comprises a first gas plenum configured to provide gas to the outer hollow cathode and a second gas plenum configured to provide gas to the inner hollow cathode.

16. The plasma processing apparatus of claim 11, comprising a filtering grid disposed between the outer hollow cathode and the inner hollow cathode and the workpiece support.

17. The plasma processing apparatus of claim 1, comprising a filtering grid disposed between the hollow cathode and the workpiece support.

18. The plasma processing apparatus of claim 1, wherein the hollow cathode is located about 20 mm to about 160 mm from the top of the workpiece when in a processing position.

19. A processing system for processing a plurality of workpieces, comprising:
a processing chamber;
a workpiece support in the processing chamber configured to support a workpiece;
a hollow cathode disposed in the processing chamber configured to produce a plasma in the processing chamber, wherein the hollow cathode is adjacent to a top of the processing chamber;
a gas distribution system configured to provide process gas to the processing chamber;
and a controller configured to operate one or more of the workpiece support, the hollow cathode, or the gas distribution system to implement a plasma treatment process.

20. A method for processing a workpiece in a plasma processing apparatus, the method comprising:
placing the workpiece on a workpiece support disposed in a processing chamber of the plasma processing apparatus;
performing a plasma treatment process on the workpiece in the processing chamber including:
generating a plasma in the processing chamber using a hollow cathode between the workpiece support and a top of the processing chamber; and
exposing the workpiece to the plasma.
